(19) United States
(12) Patent Application Publication
(10) Pub. No.: US 2019/0326404 A1
(43) Pub. Date: Oct. 24, 2019

(54) SEMICONDUCTOR DEVICE AND METHOD FOR MANUFACTURING THE SAME

(71) Applicant: FUJITSU LIMITED, Kawasaki-shi (JP)

(72) Inventors: Yusuke Kumazaki, Atsugi (JP); Toshihiro Ohki, Hadano (JP); Kozo Makiyama, Kawasaki (JP); Shirou OZAKI, Yamato (JP); Yuichi Minoura, Machida (JP)

(73) Assignee: FUJITSU LIMITED, Kawasaki-shi (JP)

(21) Appl. No.: 16/377,354

(22) Filed: Apr. 8, 2019

(30) Foreign Application Priority Data
Apr. 19, 2018 (JP) 2018-080803

(51) Int. Cl. H01L 29/417; H01L 29/20; H01L 29/205; H01L 29/45; H01L 29/778; H01L 21/306; H01L 21/285; H01L 29/66

(52) U.S. Cl. CPC H01L 29/4175; H01L 29/2003; H01L 29/205; H01L 29/66462; H01L 29/7787; H01L 21/30617; H01L 21/28587; H01L 29/452

(57) ABSTRACT

A semiconductor device includes a substrate, a first semiconductor layer formed over the substrate, the first semiconductor layer being composed of a nitride semiconductor, a second semiconductor layer formed over the first semiconductor layer, the second semiconductor layer being composed of a nitride semiconductor and a gate electrode, a source electrode, and a drain electrode that are formed over the second semiconductor layer, wherein the source electrode including a plurality of protrusions that penetrate into the second semiconductor layer, and the protrusions having a side surface inclined with respect to a surface of the first semiconductor layer.

### CROSS-REFERENCE TO RELATED APPLICATION

This application is based upon and claims the benefit of priority of the prior Japanese Patent Application No. 2018-80803, filed on Apr. 19, 2018, the entire contents of which are incorporated herein by reference.

### FIELD

The embodiments discussed herein are related to a semiconductor device and a method for manufacturing the semiconductor device.

### BACKGROUND

Nitride semiconductors, such as GaN, AlN, InN, and mixed crystals thereof have a wide band gap and are used as a material for high-power electronic devices, short-wave light-emitting devices, and the like. Among these, as for high-power electronic devices, technologies concerning to field-effect transistors (FETs) and, in particular, high-electron mobility transistors (HEMTs) have been developed. HEMTs that include a nitride semiconductor are used as a high-power, high-efficiency amplifier, a high-power switching device, or the like.

One of the FETs that include a nitride semiconductor is a HEMT that includes an electron transit layer composed of GaN and an electron supply layer composed of AlGaN. In the electron transit layer, two-dimensional electron gas (2DEG) is generated due to piezo and spontaneous polarization of GaN. In a HEMT that includes an electron transit layer composed of GaN and an electron supply layer composed of InAlN, the concentration of the 2DEG may be increased. This reduces the on-state resistance and allows a large current to flow through the HEMT.

However, in the case where the electron supply layer is composed of InAlN or AlGaN having a high Al content, which has a wide band gap, the contact resistances of source and drain electrodes, which are ohmic electrodes, may be increased and, consequently, the one-state current may be reduced.

Accordingly, there has been a demand for a semiconductor device that includes source and drain electrodes having a low contact resistance even in the case where the electron supply layer of the semiconductor device is composed of InAlN or the like having a wide band gap in order to increase the concentration of the 2DEG.

The followings are reference documents.

[Document 1] Japanese Laid-open Patent Publication No. 2017-85006,

[Document 2] Japanese Laid-open Patent Publication No. 2006-253559, and

[Document 3] Japanese Laid-open Patent Publication No. 2016-58546.

### SUMMARY

According to an aspect of the embodiments, a semiconductor device includes a substrate, a first semiconductor layer formed over the substrate, the first semiconductor layer being composed of a nitride semiconductor, a second semiconductor layer formed over the first semiconductor layer, the second semiconductor layer being composed of a nitride semiconductor and a gate electrode, a source electrode, and a drain electrode that are formed over the second semiconductor layer, wherein the source electrode including a plurality of protrusions that penetrate into the second semiconductor layer, and the protrusions having a side surface inclined with respect to a surface of the first semiconductor layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating a semiconductor device;

FIG. 2 is a diagram illustrating a semiconductor device according to a first embodiment;

FIG. 3 is a diagram used for explaining a semiconductor device according to a first embodiment;

FIG. 4 is a diagram illustrating a model electrode that simulates an electrode structure;

FIG. 5 is a diagram illustrating the correlation between the angle of a tapered protrusion formed in an electrode and the normalized contact resistance of the electrode;

FIG. 6 is a diagram illustrating the correlation between the width of a protrusion formed in an electrode and the normalized contact resistance of the electrode;

FIG. 7 is a correlation chart with an area ratio of a protrusion and standardized contact resistance of the electrode;

FIG. 8 is a diagram illustrating a determined correlation between the area ratio of a protrusion formed in an electrode and the normalized contact resistance of the electrode;

FIGS. 9A and 9B are diagrams illustrating a step of the method for manufacturing a semiconductor device according to a first embodiment (1);

FIGS. 10A and 10B are diagrams illustrating a step of the method for manufacturing a semiconductor device according to a first embodiment (2);

FIGS. 11A and 11B are diagrams illustrating a step of the method for manufacturing a semiconductor device according to a first embodiment (3);

FIG. 12 is a diagram illustrating a step of the method for manufacturing a semiconductor device according to a first embodiment (4);

FIG. 13 is a diagram illustrating a modification example 1 of a semiconductor device according to a first embodiment;

FIG. 14 is a diagram illustrating a modification example 2 of a semiconductor device according to a first embodiment;

FIG. 15 is a diagram illustrating a modification example 3 of a semiconductor device according to a first embodiment;

FIG. 16 is a diagram illustrating a modification example 4 of a semiconductor device according to a first embodiment;

FIG. 17 is a diagram illustrating a semiconductor device according to a second embodiment;

FIG. 18 is a diagram illustrating a semiconductor device according to a third embodiment;

FIG. 19 is a diagram illustrating a semiconductor device according to a fourth embodiment;

FIG. 20 is a diagram illustrating a semiconductor device according to a fifth embodiment;

FIG. 21 is a diagram used for explaining a discretely packaged semiconductor device according to a sixth embodiment;

FIG. 22 is a circuit diagram of a power supply device according to a sixth embodiment; and

FIG. 23 is a diagram illustrating a high-power amplifier according to a sixth embodiment.

### DESCRIPTION OF EMBODIMENTS

Embodiments are described below. Hereinafter, the same elements and the like are denoted by the same reference numeral, and the description thereof is omitted. The horizontal and vertical scales and the like of the drawings may be changed from the actual one for the sake of simplicity.

### First Embodiment

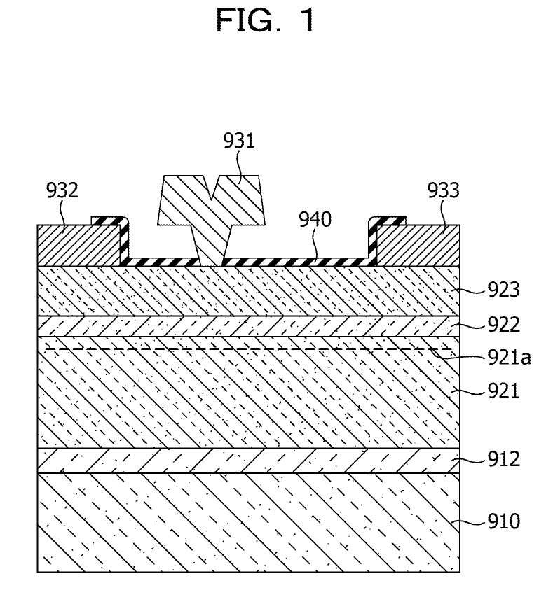

The contact resistances of source and drain electrodes included in a HEMT that includes an electron transit layer composed of GaN and an electron supply layer composed of InAlN are described below with reference to FIG. 1. The semiconductor device illustrated in FIG. 1 includes a substrate 910 and a buffer layer 912, an electron transit layer 921, a spacer layer 922, and an electron supply layer 923 that are stacked on and above the substrate 910 by epitaxial growth of nitride semiconductors. The substrate 910 is composed of SiC or the like. The buffer layer 912 is composed of AlN, GaN, or the like. The electron transit layer 921 is composed of i-GaN. The spacer layer 922 is composed of AlN. The electron supply layer 923 is composed of InAlN. As a result, 2DEG 921a is generated in a portion of the electron transit layer 921 which is in the vicinity of the interface between the electron transit layer 921 and the spacer layer 922. A gate electrode 931, a source electrode 932, and a drain electrode 933 are formed on the electron supply layer 923. An insulating film 940 is formed on the electron supply layer 923 so as to cover the exposed surface of the electron supply layer 923.

Since the electron supply layer 923 included in the semiconductor device illustrated in FIG. 1 is composed of InAlN, which has a wide band gap, the source electrode 932 and the drain electrode 933 formed on the electron supply layer 923, which are ohmic electrodes, have a high contact resistance. Therefore, the amount of current that can flow through the semiconductor device is disadvantageously limited even when the concentration of 2DEG 921a is increased by forming the electron supply layer 923 using InAlN, because of the high contact resistances of the source electrode 932 and the drain electrode 933.

Accordingly, there has been a demand for a semiconductor device that includes source and drain electrodes having a low contact resistance even in the case where the electron supply layer 923 is composed of InAlN in order to increase the concentration of the 2DEG.

[Semiconductor Device]

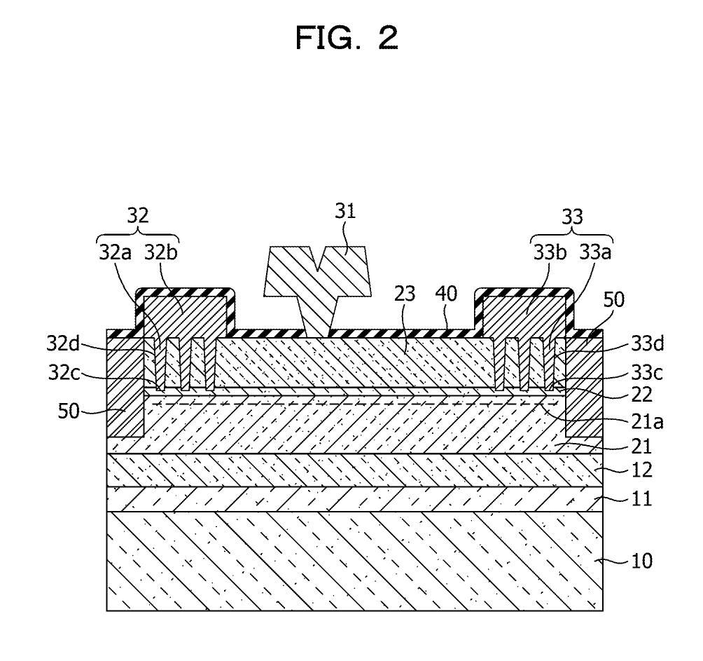

A semiconductor device according to the first embodiment is described below with reference to FIG. 2. The semiconductor device according to the first embodiment includes a substrate 10 and a nucleation layer 11, a buffer layer 12, an electron transit layer 21, a spacer layer 22, and an electron supply layer 23 that are stacked on and above the substrate 10 by epitaxial growth of nitride semiconductors. The substrate 10 is composed of SiC or the like and may alternatively be composed of Si, sapphire, GaN, AlN, diamond, or the like. The nucleation layer 11 is composed of AlN or the like. The buffer layer 12 is composed of AlN, GaN, or the like. The electron transit layer 21 is composed of i-GaN. The spacer layer 22 is composed of AlN. The electron supply layer 23 is composed of InAlN. As a result, 2DEG 21a is generated in a portion of the electron transit layer 21 which is in the vicinity of the interface between the electron transit layer 21 and the spacer layer 22.

In the first embodiment, the spacer layer 22 has a thickness of 1 nm, and the electron supply layer 23 has a thickness of 6 nm. The spacer layer 22 may alternatively be composed of AlGaN or the like. An element separation region 50 is formed in the nitride semiconductor layers. Hereinafter, the electron transit layer 21 is referred to as “first semiconductor layer”, the electron supply layer 23 is referred to as “second semiconductor layer”, and the spacer layer 22 is referred to as “third semiconductor layer”.

A gate electrode 31, a source electrode 32, and a drain electrode 33 are formed on the electron supply layer 23. An insulating film 40 is formed on the electron supply layer 23 so as to cover the exposed surface of the electron supply layer 23. The source electrode 32 is constituted by a plurality of protrusions 32a that penetrate into the nitride semiconductor layers and an electrode main body 32b, which is the portion of the source electrode 32 which is above the nitride semiconductor layers. The lower edges 32c of the protrusions 32a are in contact with the spacer layer 22. Each of the protrusions 32a of the source electrode 32 includes a side surface 32d that is inclined such that the width of the protrusion 32a gradually decreases in the direction from the electrode main body 32b, that is, the surface of the electron supply layer 23, toward the edges 32c. Similarly to the source electrode 32, the drain electrode 33 is constituted by a plurality of protrusions 33a that penetrate into the nitride semiconductor layers and an electrode main body 33b, which is the portion of the drain electrode 33 which is above the nitride semiconductor layers. The lower edges 33c of the protrusions 33a are in contact with the spacer layer 22. Each of the protrusions 33a of the drain electrode 33 includes a side surface 33d that is inclined such that the width of the protrusion 33a gradually decreases in the direction from the electrode main body 33b, that is, the surface of the electron supply layer 23, toward the edges 33c.

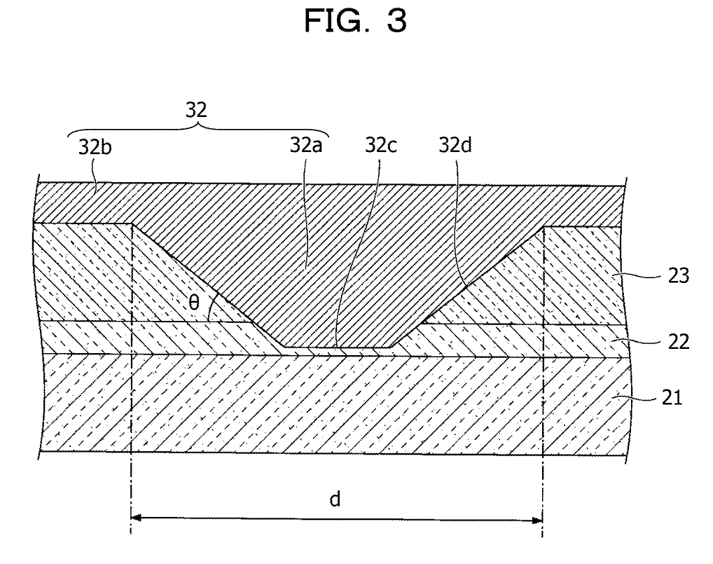

Further details are given below with reference to FIG. 3, taking the protrusions 32a of the source electrode 32 as an example. As illustrated in FIG. 3, the source electrode 32 is constituted by an electrode main body 32b, which is the portion of the source electrode 32 which is above the electron supply layer 23, and a protrusion 32a that penetrates into the electron supply layer 23 and a part of the spacer layer 22. The edge 32c of the protrusion 32a of the source electrode 32 is a portion of the source electrode 32 which serves as the lowermost surface of the source electrode 32 and is in contact with the spacer layer 22. The protrusion 32a of the source electrode 32 is tapered. For example, the side surface 32d of the protrusion 32a is inclined such that the width of the protrusion 32a gradually decreases in the direction from the electrode main body 32b toward the edge 32c. The side surface 32d of the protrusion 32a of the source electrode 32 is inclined at an angle θ with respect to the interface between the spacer layer 22 and the electron supply layer 23. The protrusions 33a of the drain electrode 33 have the same structure as that of the source electrode 32 illustrated in FIG. 3. Hereinafter, the above angle θ is referred to as “angle θ of the tapered protrusions 32a”, and the width d of the protrusion 32a on the electrode main body 32b-side is referred to as “width d of the protrusion 32a”. In the case where the protrusion 32a is pit-like, the width d of the protrusion 32a corresponds to the diameter of the protrusion 32a. In the case where the protrusion 32a is linear, the width d of the protrusion 32a corresponds to the width of the line.

[Simulation]

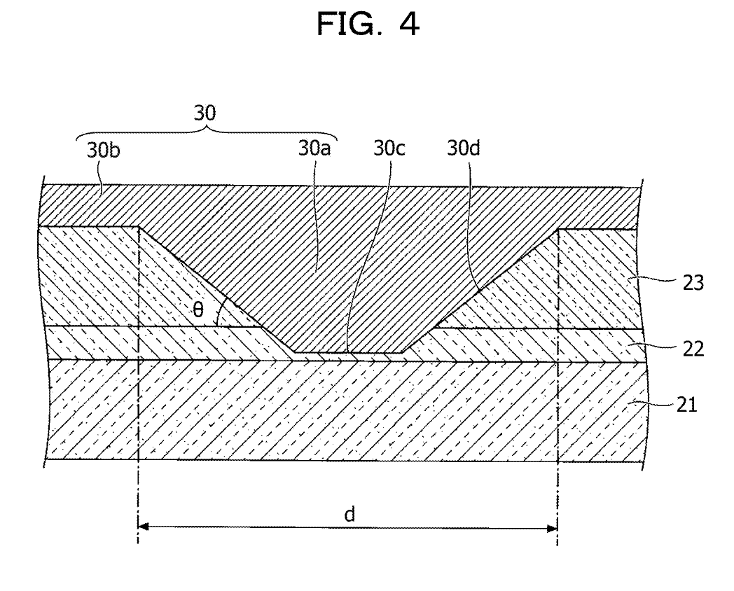

The results of a simulation performed on a model electrode 30 illustrated in FIG. 4 are described below. The electrode 30 corresponds to the source electrode 32 and the drain electrode 33 and is constituted by an electrode main body 30b, which is the portion of the electrode 30 which is above the electron supply layer 23, and a protrusion 30a that penetrates into the electron supply layer 23 and a part of the spacer layer 22. The side surface 30d of the protrusion 30a is inclined at an angle θ with respect to the interface between the spacer layer 22 and the electron supply layer 23. The width of the protrusion 30a on the electrode main body 30b-side is “d”.

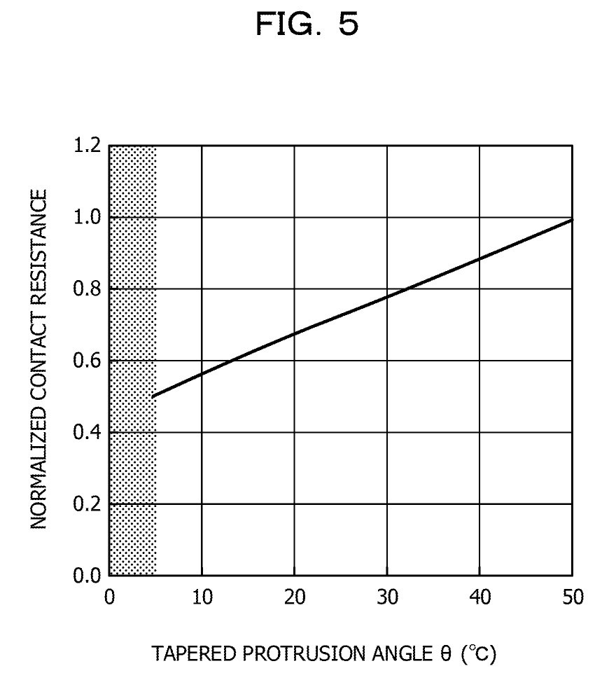

FIG. 5 illustrates the correlation between the angle θ of the side surface 30d of the protrusion 30a and the normalized contact resistance of the electrode 30 which holds in the case where the width d of the protrusion 30a is 100 nm. In FIG. 5, the contact resistance of the electrode 30 is normalized with the contact resistance of an electrode that does not have any protrusion formed therein as illustrated in FIG. 1 being 1.0. As illustrated in FIG. 5, when the angle θ is 5°, the normalized contact resistance is about 0.5, and the larger the angle θ, the higher the normalized contact resistance. When the angle θ is 30°, the normalized contact resistance is 0.78. The normalized contact resistance is less than about 1.0 when the angle θ is 50° and is 1.0 or more when the angle θ is more than 50°. It is considerably difficult and not practical to form protrusions having an angle θ of less than 5°. Since it is preferable to minimize the contact resistance, the normalized contact resistance is preferably less than 1.0 and is further preferably 0.8 or less. Accordingly, the angle θ of the tapered protrusion 30a is preferably 5° or more and 50° or less and is further preferably 5° or more and 30° or less.

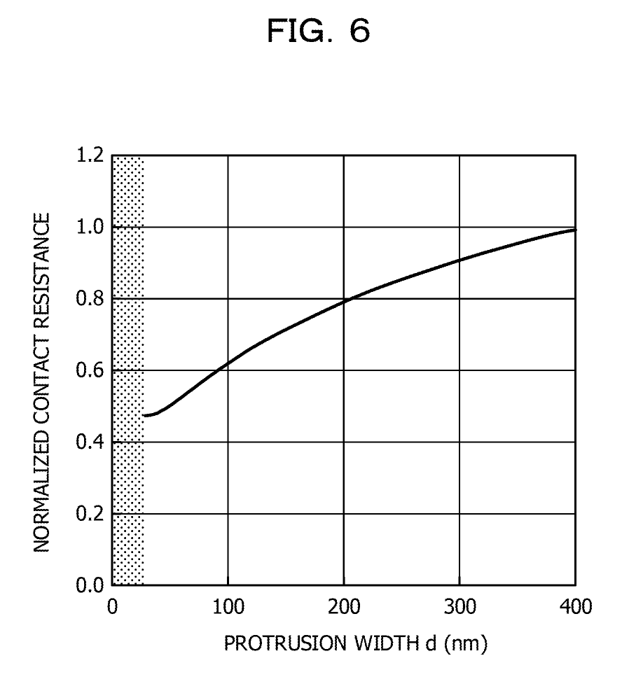

FIG. 6 illustrates the correlation between the width d of the protrusion 30a and the normalized contact resistance of the electrode 30 which holds in the case where the angle θ of the tapered protrusion 30a is 20°. In FIG. 6, the contact resistance of the electrode 30 is normalized with the contact resistance of an electrode that does not have any protrusion formed therein as illustrated in FIG. 1 being 1.0. As illustrated in FIG. 6, when the width d of the protrusion 30a is 20 nm, the normalized contact resistance is about 0.5, and the larger the width d of the protrusion 30a, the higher the normalized contact resistance. When the width d of the protrusion 30a is 200 nm, the normalized contact resistance is 0.79. The normalized contact resistance is less than about 1.0 when the width d of the protrusion 30a is 400 nm and is 1.0 or more when the width d of the protrusion 30a is more than 400 nm. It is considerably difficult and not practical to form protrusions such that the width d of the protrusion 30a is less than 20 nm. For example, the protrusion 30a is formed by filling an opening that is a groove formed in a portion of the electron supply layer 23 in which the electrode 30 is to be formed with a metal by vacuum vapor deposition or the like. If the width of the opening is small, the opening may fail to be filled with a metal and it becomes not possible to form the protrusion 30a. Accordingly, the width d of the protrusion 30a is preferably 20 nm or more and 400 nm or less and is further preferably 20 nm or more and 200 nm or less.

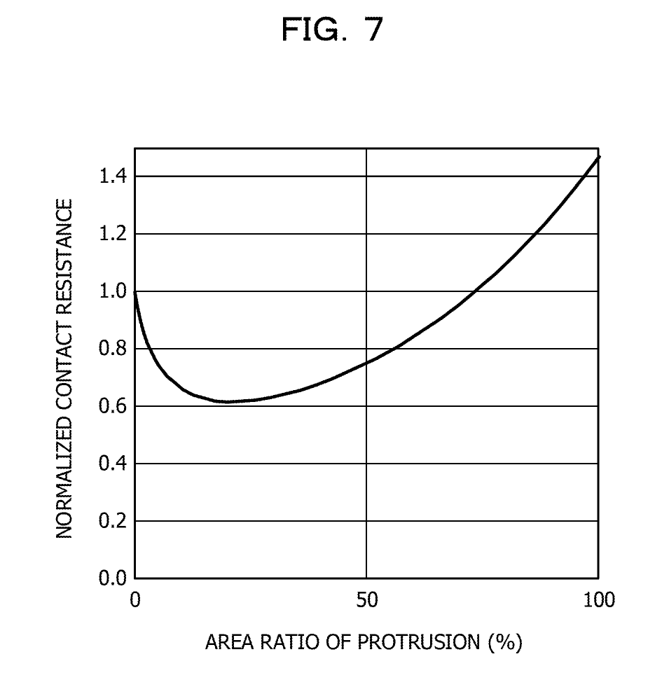

FIG. 7 illustrates the correlation between the area ratio of the protrusion 30a in a cross section of the electrode 30 which is taken along the surface of the electron supply layer 23 and the normalized contact resistance of the electrode 30. The area ratio of the protrusion 30a is the ratio of the area of a portion of the cross section of the electrode 30 which is taken along the surface of the electron supply layer 23 on which the protrusion 30a is formed to the total area of the cross section of the electrode 30. The area ratio of the protrusion 30a is the area ratio of the portion that corresponds to the width d of the protrusion 30a. In FIG. 7, the contact resistance of the electrode 30 is normalized with the contact resistance of an electrode that does not have any protrusion formed therein as illustrated in FIG. 1 being 1.0. The area ratio of the protrusion 30a being 0% corresponds to an electrode that does not have any protrusion 30a formed therein. The protrusion 30a is tapered at an angle θ of 20° and has a width d of 100 nm. The area ratio of the protrusion 30a is changed by increasing the number of the protrusions 30a. As illustrated in FIG. 7, when the area ratio of the protrusion 30a is 0%, the normalized contact resistance is 1.0. When the area ratio of the protrusion 30a is about 3%, the normalized contact resistance is about 0.8. That is, the larger the area ratio of the protrusion 30a, the lower the normalized contact resistance. The normalized contact resistance is minimized when the area ratio of the protrusion 30a is around 20%. When the area ratio of the protrusion 30a is larger than about 20%, the larger the area ratio of the protrusion 30a, the higher the normalized contact resistance. When the area ratio of the protrusion 30a is about 55%, the normalized contact resistance is about 0.8. The normalized contact resistance is less than 1.0 when the area ratio of the protrusion 30a is about 73% and is 1.0 or more when the area ratio of the protrusion 30a is more than about 73%.

Accordingly, the area ratio of the protrusion 30a is preferably more than 0% and 73% or less and is further preferably 3% or more and 55% or less.

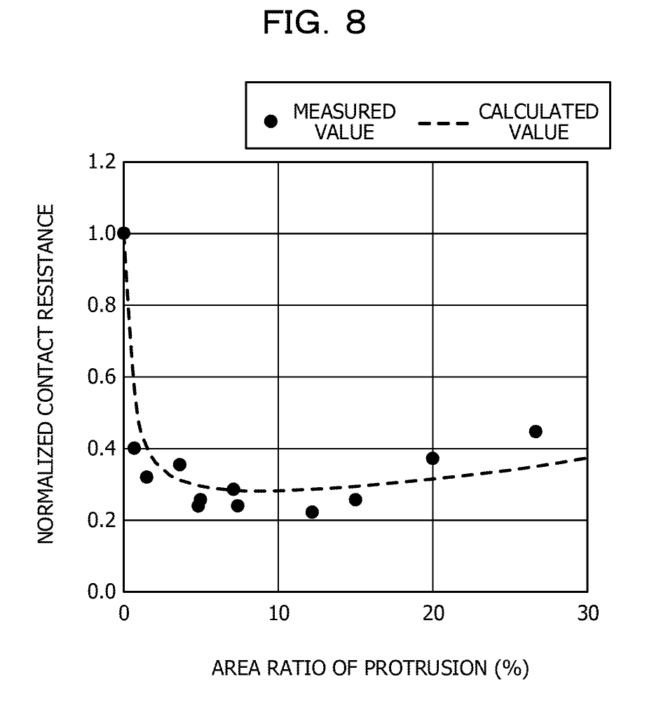

FIG. 8 illustrates the contact resistances of electrodes 30 having the structure illustrated in FIG. 4 which were prepared such that the area ratio of the protrusion 30a varied one by one. The contact resistances of the electrodes 30 were measured by a transfer length method (TLM) and normalized with the contact resistance of an electrode that does not have any protrusion formed therein being 1.0. The contact resistance of the protrusion 30a of each of the electrodes 30 was determined based on the results of the above measurement and the contact resistance ρ_{b} (5.2×10⁻⁴ Ω·cm²) at the interface between the electrode main body 30b and the electron supply layer 23 which had been measured by a test. The resistivity ρ_{c} at the interface between the edge 30c of the protrusion 30a and the nitride semiconductor layer was considered high since the 2DEG is absent and assumed to be 1.0×10⁻² Ω·cm². As a result, it was found that the resistivity ρ_{d} at the interface between the tapered side surface 30d of the protrusion 30a and the nitride semiconductor layers was 1.3×10⁻⁶ Ω·cm², which is about 1/400 of the resistivity ρ_{b}. This confirms that the contact resistance of the electrode 30 can be reduced by forming the protrusion 30a having the tapered side surface 30d in the electrode 30. FIG. 8 also illustrates the normalized contact resistances calculated based on the resistivity values ρ_{b}, ρ_{c}, and ρ_{d} with a broken line.

### Method for Manufacturing Semiconductor Device

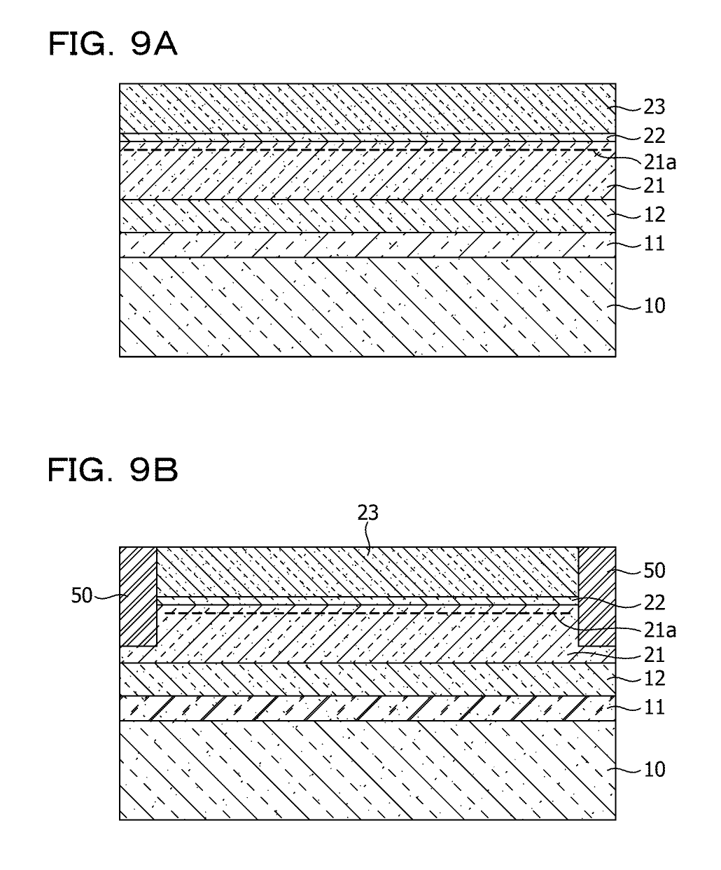

A method for manufacturing the semiconductor device according to the first embodiment is described below with reference to FIGS. 9A to 12.

First, as illustrated in FIG. 9A, nitride semiconductor layers are epitaxially grown on the substrate 10 to form a nucleation layer 11, a buffer layer 12, an electron transit layer 21, a spacer layer 22, and an electron supply layer 23. As a result, 2DEG 21a is generated in a portion of the electron transit layer 21 which is in the vicinity of the interface between the electron transit layer 21 and the spacer layer 22. The epitaxial growth of the nitride semiconductor layers is performed using metal organic vapor phase epitaxy (MOVPE).

Although the substrate 10 used in the first embodiment is a SiC substrate, the substrate 10 may be a sapphire substrate, a Si substrate, a SiC substrate, or a GaN substrate. The nucleation layer 11 is composed of AlN or the like. The buffer layer 12 is composed of AlGaN or the like. The electron transit layer 21 is an i-GaN layer having a thickness of 3 μm. The spacer layer 22 is an AlN layer having a thickness of 1 nm. The electron supply layer 23 is an InAlN layer having a thickness of 6 nm. The electron supply layer 23 may alternatively be composed of InAlGaN.

As illustrated in FIG. 9B, element separation regions 50, which separate elements from one another, are formed in the nitride semiconductor layers. For example, a photoresist is applied onto the electron supply layer 23, and the resulting coating film is exposed to light with an exposure device and developed into a resist pattern (not illustrated) having openings corresponding to the positions at which the element separation regions 50 are to be formed. Argon (Ar) ions were injected into the portions of the nitride semiconductor layers on which the resist pattern is not formed in order to form the element separation regions 50. The element separation regions 50 may alternatively be formed by partially removing the portions of the nitride semiconductor layers on which the resist pattern is not formed by dry etching, such as reactive ion etching (RIE) with a chlorine-containing gas. The resist pattern is removed using an organic solvent or the like subsequent to the formation of the element separation regions 50.

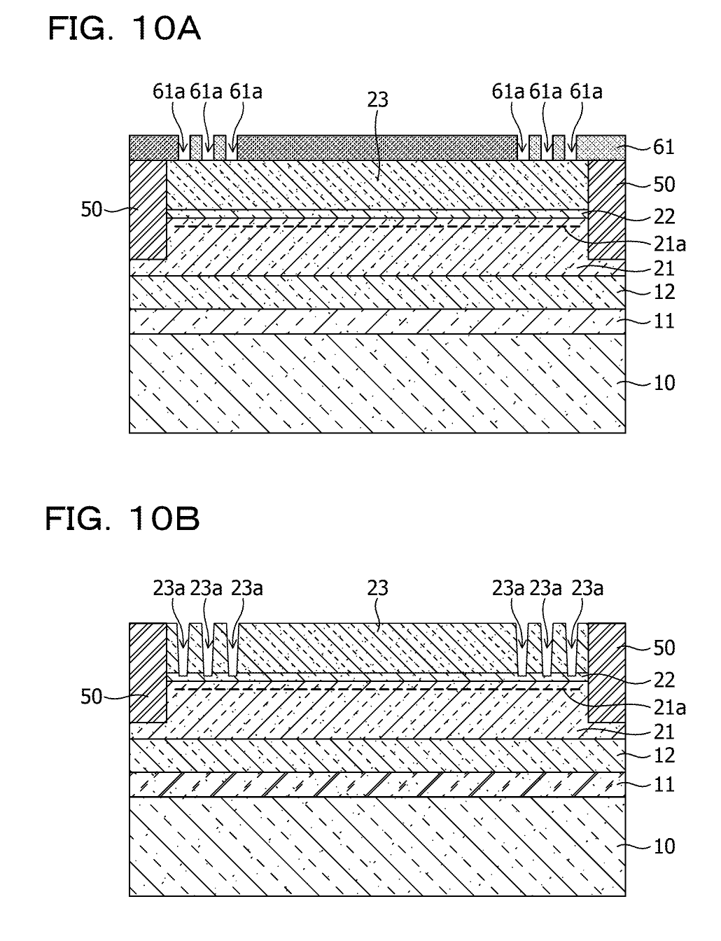

As illustrated in FIG. 10A, a hardmask 61 is formed on the nitride semiconductor layers. The hardmask 61 is used for forming the protrusions 32a of the source electrode 32 and the protrusions 33a of the drain electrode 33. For example, a SiN film having a thickness of 50 nm is formed on the electron supply layer 23 and the element separation regions 50 by plasma chemical vapor deposition (CVD). A photoresist is applied onto the SiN film. The resulting coating film is exposed to light with an exposure device and developed into a resist pattern (not illustrated) having openings. Portions of the SiN film on which the resist pattern is not formed are removed by dry etching, such as RIE, to form openings 61a in the SiN film. The surface of the electron supply layer 23 is exposed through the openings 61a. The remaining SiN film forms a hardmask 61 having openings 61a. The openings 61a of the hardmask 61 are formed at the positions that correspond to the positions of the protrusions 32a of the source electrode 32 and the protrusions 33a of the drain electrode 33. Subsequently, the resist pattern (not illustrated) is removed using an organic solvent or the like.

As illustrated in FIG. 10B, the portions of the electron supply layer 23 and the spacer layer 22 in which the protrusions 32a of the source electrode 32 and the protrusions 33a of the drain electrode 33 are to be formed are removed in order to form openings 23a. For example, portions of the electron supply layer 23 which are exposed through the openings 61a of the hardmask 61 are removed by wet etching. Subsequently, portions of the spacer layer 22 which are exposed through the openings 61a are partially removed by wet etching. As a result, openings 23a are formed in the portions of the electron supply layer 23 and the spacer layer 22 in which the protrusions 32a of the source electrode 32 and the protrusions 33a of the drain electrode 33 are to be formed. Since wet etching enables isotropic etching of nitride semiconductor layers, it is possible to form, by wet etching, the openings 23a that are tapered such that the openings 23a have a larger width on the surface side of the electron supply layer 23 and a smaller width on the bottom side of the openings 23a. Examples of an etchant used in the above wet etching include tetramethylammonium hydroxide (TMAH), potassium hydroxide, sodium hydroxide, sulfuric acid, a hydrogen peroxide solution, and mixed solutions thereof. The temperature of the etchant and the agitation speed may be changed in order to change the shape of the openings 23a and the etch rate. The tapered openings 23a may also be formed by using plasma etching with a chlorine-containing gas instead of wet etching. Subsequent to the formation of the openings 23a, the hardmask 61 is removed using another etchant that removes only SiN but does not remove the nitride semiconductors. The openings 23a formed in the electron supply layer 23 and a part of the spacer layer 22 may be circular, polygonal, linear, or the like when viewed in the plane of the electron supply layer 23.

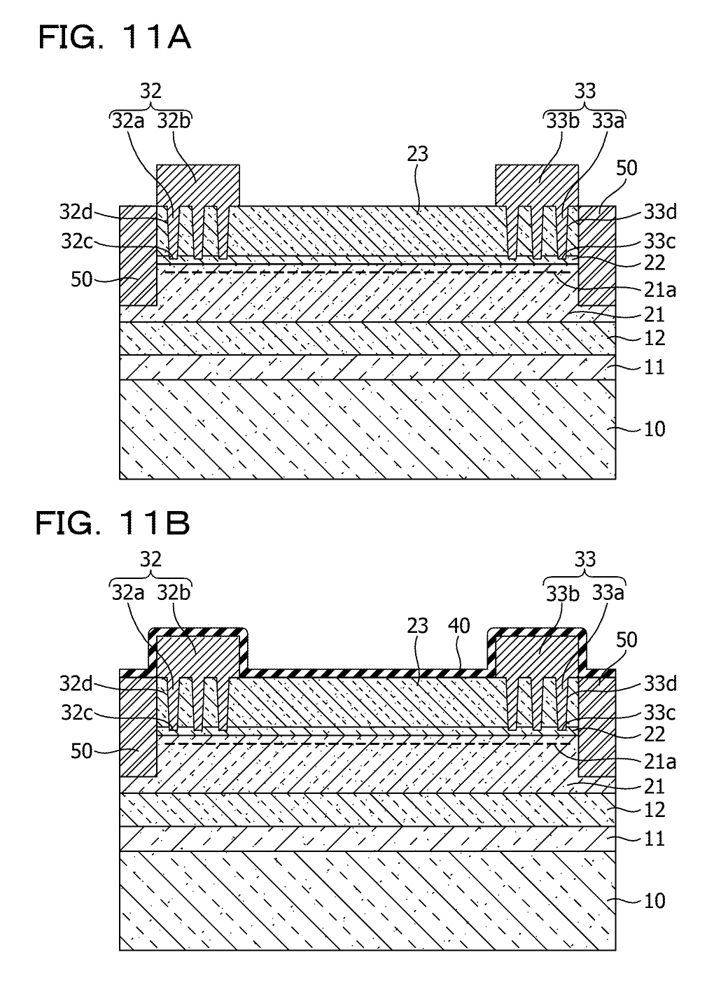

As illustrated in FIG. 11A, a source electrode 32 and a drain electrode 33 are formed on the electron supply layer 23. For example, a photoresist is applied onto the electron supply layer 23 and so on. The resulting coating film is exposed to light with an exposure device and developed into a resist pattern (not illustrated) having openings that correspond to the positions at which the source electrode 32 and the drain electrode 33 are to be formed. Subsequent to the formation of the resist pattern, a metal coating film composed of Ti/Al is formed on the resist pattern by vacuum vapor deposition and then immersed in an organic solvent in order to remove the resist pattern and a portion of the metal coating film which is formed on the resist pattern by lift-off. The other portions of the metal coating film which remain on the electron supply layer 23 form a source electrode 32 and a drain electrode 33. As described above, when the metal coating film is formed by vacuum vapor deposition, the openings 23a formed in the electron supply layer 23 and a part of the spacer layer 22 are filled with the metal coating film and, consequently, the protrusions 32a of the source electrode 32 and the protrusions 33a of the drain electrode 33 are formed. The metal coating film composed of Ti/Al is a multilayer film consisting of a Ti film having a thickness of 2 to 50 nm and an Al film having a thickness of 100 to 300 nm and is formed such that the Ti film comes into contact with the electron supply layer 23 and so on. Subsequently, a heat treatment is performed in a nitrogen atmosphere at a temperature of 500° C. to 900° C., that is, for example, about 600° C., in order to establish an ohmic contact at the source electrode 32 and the drain electrode 33.

As illustrated in FIG. 11B, an insulating film 40 that is a passivation film is formed on the electron supply layer 23 and so on by plasma CVD. The insulating film 40 is composed of SiN or the like and has a thickness of 2 to 1000 nm, that is, for example, 100 nm. For forming the insulating film 40, atomic layer deposition (ALD) and sputtering may be used alternatively. The insulating film 40 may be composed of a substance other than SiN which is an oxide, a nitride, or an oxynitride of Si, Al, Hf, Zr, Ta, or the like.

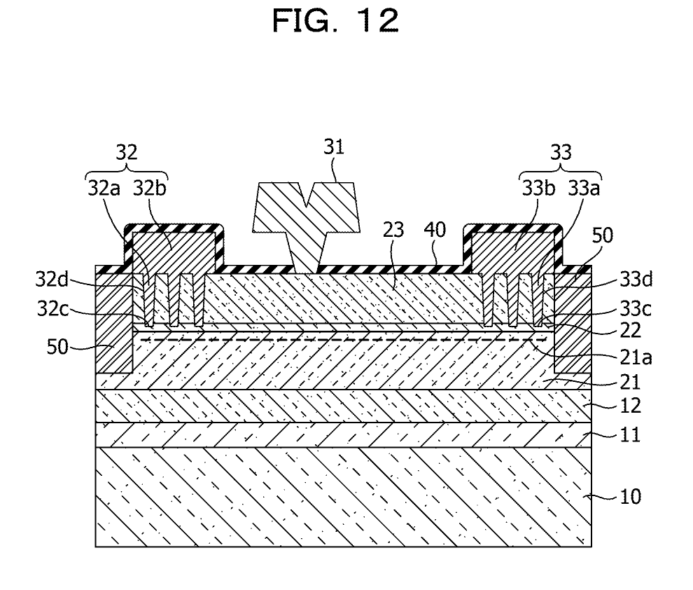

As illustrated in FIG. 12, a gate electrode 31 is formed on the electron supply layer 23. For example, a photoresist is applied onto the insulating film 40. The resulting coating film is exposed to light with an exposure device and developed into a resist pattern (not illustrated) having an opening that corresponds to the position at which the gate electrode 31 is to be formed. A portion of the insulating film 40 which is exposed through the opening of the resist pattern is removed by dry etching, such as RIE with a fluorine-containing gas, in order to form an opening in the insulating film 40 through which the electron supply layer 23 is exposed. Subsequent to the formation of the opening of the insulating film 40, the resist pattern is immersed in an organic solvent or the like in order to remove the resist pattern. Then, a photoresist is applied onto the insulating film 40 and the electron supply layer 23. The resulting coating film is exposed to light with an exposure device and developed into a resist pattern (not illustrated) having an opening that corresponds to the position at which the gate electrode 31 is to be formed. A metal coating film composed of Ni/Au is formed on the resist pattern by vacuum vapor deposition and then immersed in an organic solvent in order to remove the resist pattern and a portion of the metal coating film which is formed on the resist pattern by lift-off. The remaining portion of the metal coating film forms a gate electrode 31 on the electron supply layer 23. The metal coating film composed of Ni/Au is a multilayer film consisting of a Ni film having a thickness of about 10 nm and an Au film having a thickness of about 300 nm and is formed such that the Ni film comes into contact with the electron supply layer 23.

The semiconductor device according to the first embodiment is produced through the above-described steps.

### Modification Examples

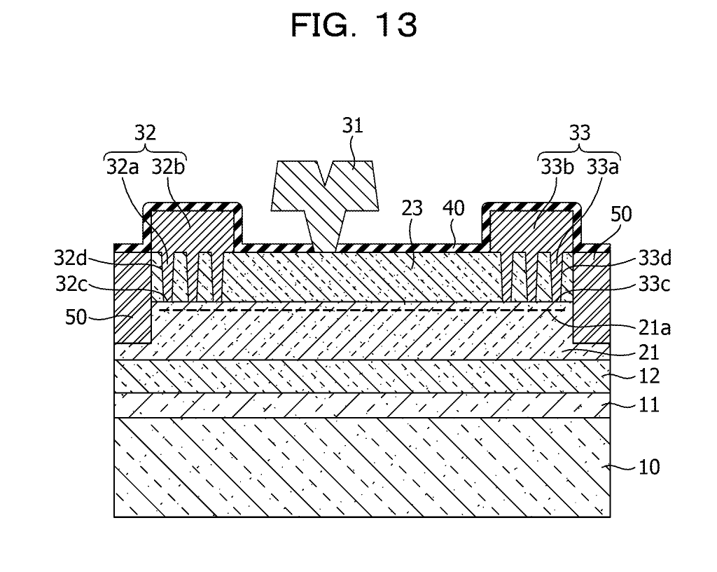

The semiconductor device according to the first embodiment does not necessarily include the spacer layer 22 interposed between the electron transit layer 21 and the electron supply layer 23, as illustrated in FIG. 13. For example, in the semiconductor device according to the first embodiment, the electron supply layer 23 may be formed on the electron transit layer 21. In such a semiconductor device, although not illustrated in the drawing, the side surfaces 32d of the protrusions 32a of the source electrode 32 and the side surfaces 33d of the protrusions 33a of the drain electrode 33 are inclined at an angle θ with respect to the interface between the electron transit layer 21 and the electron supply layer 23.

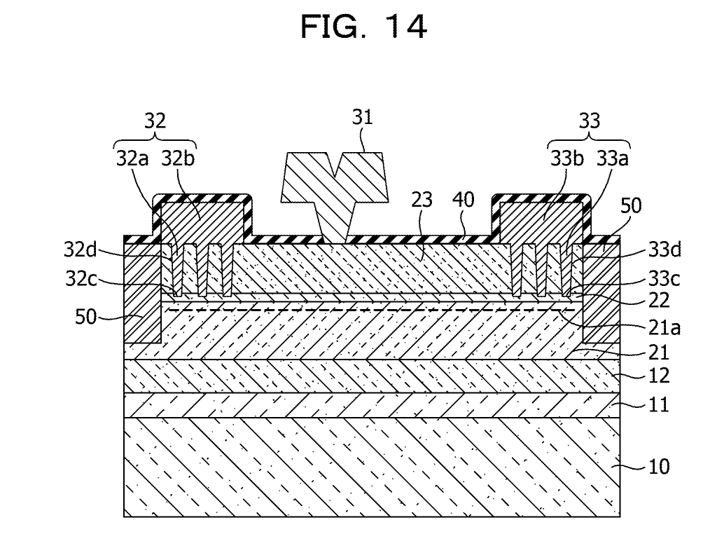

In the semiconductor device according to the first embodiment, the gate electrode 31 may be formed on the insulating film 40 as illustrated in FIG. 14. In such a case, the insulating film 40 serves as a gate insulating film and may reduce the gate leakage current.

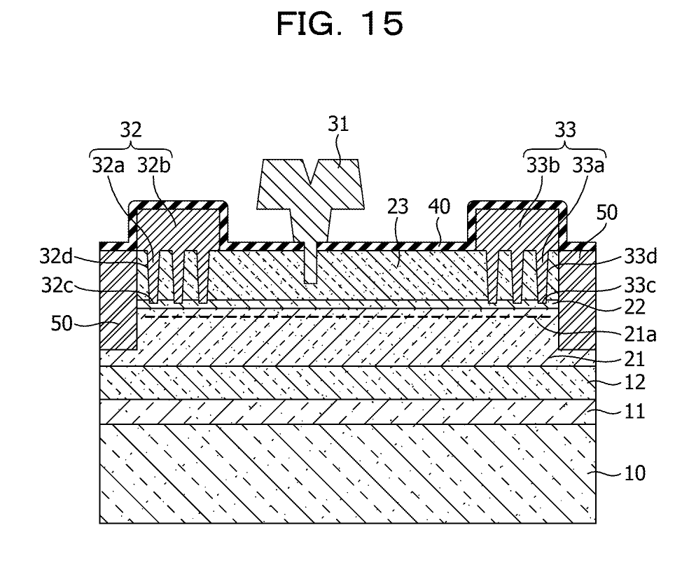

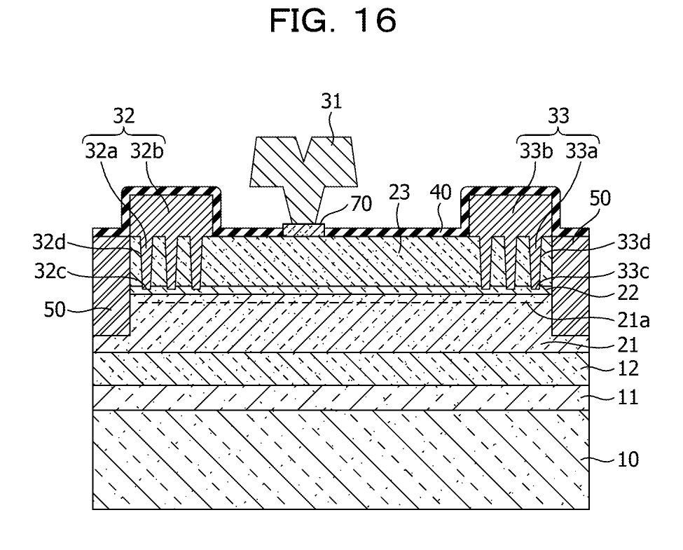

In the semiconductor device according to the first embodiment, a gate recess may be formed in the electron supply layer 23 as illustrated in FIG. 15. In another case, a p-GaN layer 70 may be formed on the electron supply layer 23 and the gate electrode 31 may be formed on the p-GaN layer 70 as illustrated in FIG. 16.

### Second Embodiment

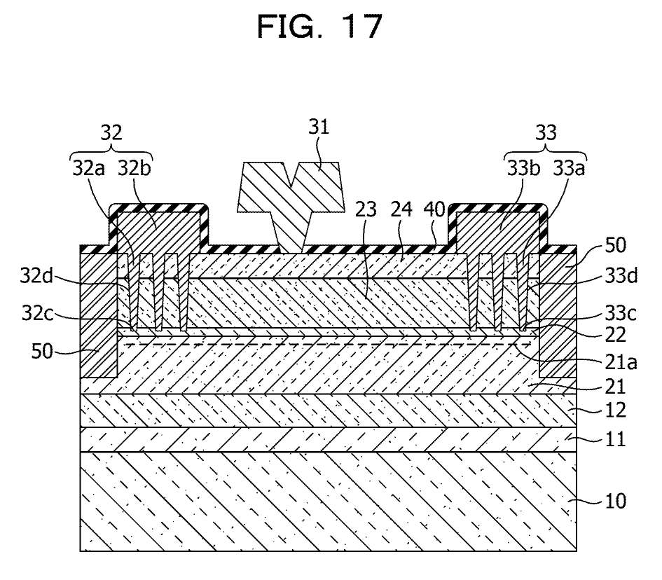

A semiconductor device according to the second embodiment is described below. The semiconductor device according to the second embodiment includes a cap layer 24 formed on the electron supply layer 23 as illustrated in FIG. 17. For example, the semiconductor device according to the second embodiment includes a substrate 10 and a nucleation layer 11, a buffer layer 12, an electron transit layer 21, a spacer layer 22, an electron supply layer 23, and a cap layer 24 that are stacked on and above the substrate 10 by epitaxial growth of nitride semiconductors. Hereinafter, the cap layer 24 is referred to as “fourth semiconductor layer”. In the second embodiment, the cap layer 24 is a semiconductor layer having a thickness of 5 nm which is composed of i-GaN, n-GaN, or the like.

In the semiconductor device according to the second embodiment, a gate electrode 31, a source electrode 32, and a drain electrode 33 are formed on the cap layer 24. Furthermore, an insulating film 40 is formed on the cap layer 24 so as to cover the exposed surface of the cap layer 24. The source electrode 32 includes a plurality of protrusions 32a that penetrate into the nitride semiconductor layers. The edges 32c of the protrusions 32a are in contact with the spacer layer 22. Similarly to the source electrode 32, the drain electrode 33 includes a plurality of protrusions 33a that penetrate into the nitride semiconductor layers. The edges 33c of the protrusions 33a are in contact with the spacer layer 22.

Elements other than those described above are the same as in the first embodiment.

### Third Embodiment

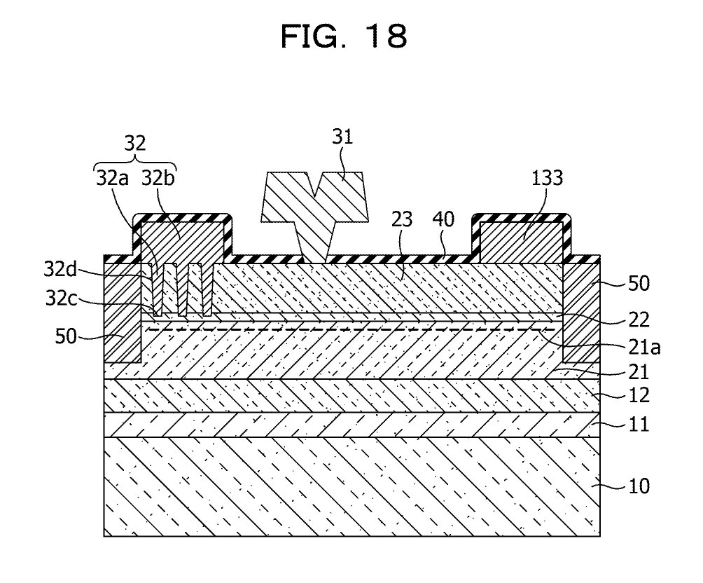

A semiconductor device according to the third embodiment is described below. In the semiconductor device according to the third embodiment, the protrusions are not formed in the drain electrode 133, while the source electrode 32 has the protrusions 32a formed therein as illustrated in FIG. 18. When the protrusions 32a are formed only in the source electrode 32, the drain electrode 133 has a higher contact resistance than the source electrode 32. This may reduce excessive concentration of the electric field at, for example, a position immediately below the gate electrode 31 and consequently increase the pressure resistance of the semiconductor device.

Elements other than those described above are the same as in the first embodiment.

### Fourth Embodiment

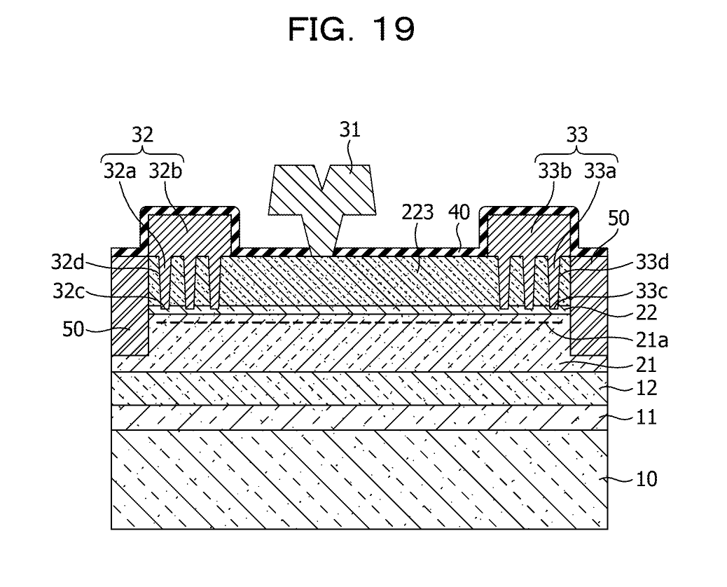

A semiconductor device according to the fourth embodiment is described below. The semiconductor device according to the fourth embodiment includes an electron supply layer 223 composed of AlGaN having an Al content of 0.5 or more, that is, AlN or AlₓGa₁₋ₓN (x≥0.5), as illustrated in FIG. 19. For example, the semiconductor device according to the fourth embodiment includes a substrate 10 and a nucleation layer 11, a buffer layer 12, an electron transit layer 21, a spacer layer 22, and an electron supply layer 223 stacked on and above the substrate 10 by epitaxial growth of nitride semiconductors. Hereinafter, the electron supply layer 223 is referred to as “second semiconductor layer”.

Since AlGaN having an Al content of 0.5 or more has a wide band gap, forming the source or drain electrode on the AlGaN layer having an Al content of 0.5 or more, which serves as an electron supply layer, increases the contact resistance. Partially removing the electron supply layer 223 and spacer layer 22 and forming the source electrode 32 including the protrusions 32a and the drain electrode 33 including the protrusions 33a may reduce the contact resistances of the source electrode 32 and the drain electrode 33.

Elements other than those described above are the same as in the first embodiment. The technology according to the fourth embodiment may be applied to the second and third embodiments.

### Fifth Embodiment

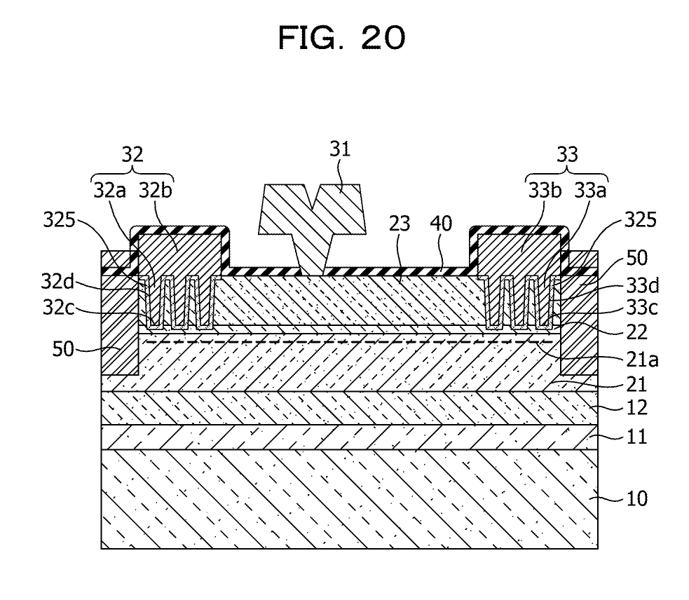

A semiconductor device according to the fifth embodiment is described below. The semiconductor device according to the fifth embodiment includes n-type semiconductor layers 325 formed on portions of the nitride semiconductor layers which come into contact with the source electrode 32 and the drain electrode 33 as illustrated in FIG. 20. Forming the n-type semiconductor layers 325 in the portions of the nitride semiconductor layers which come into contact with the source electrode 32 and the drain electrode 33 enables a sharp band structure to be created at the interface, increases the tunneling probability of electrons, and, consequently, may further reduce the contact resistance. The n-type semiconductor layers 325 are composed of GaN doped with an impurity element, such as Si or Ge. The concentration of the impurity element in GaN is 2×10¹⁹ cm⁻³ or more.

The semiconductor device according to the fifth embodiment is produced by forming openings in the electron supply layer 23 and the spacer layer 22, forming n-type semiconductor layers 325 in the openings by crystal growth of n-GaN or the like or ion implantation of an n-type impurity element, and forming a source electrode 32 and a drain electrode 33 on the n-type semiconductor layer 325.

Elements other than those described above are the same as in the first embodiment.

### Sixth Embodiment

The sixth embodiment is described below. The sixth embodiment relates to a semiconductor device, a power supply device, and a high-frequency amplifier.

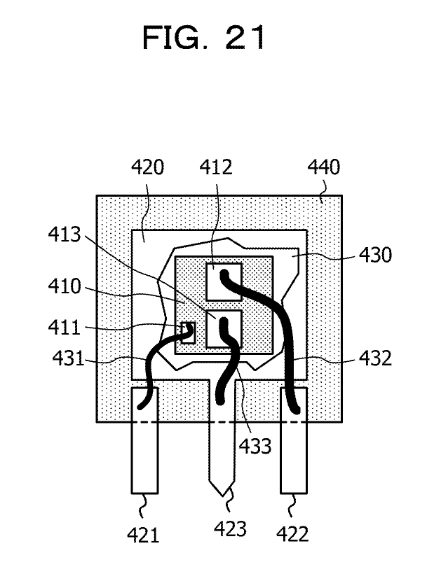

The semiconductor device according to the sixth embodiment is produced by discretely packaging the semiconductor device according to any one of the first to fifth embodiments. The discretely packaged semiconductor device is described with reference to FIG. 21. FIG. 21 schematically illustrates the inside of a discretely packaged semiconductor device; the positions and so on of the electrodes illustrated in FIG. 21 are different from those described in the first to fifth embodiments.

The semiconductor device according to any one of the first to fifth embodiments is cut, by dicing or the like, into a semiconductor chip 410 that is, for example, a HEMT including GaN semiconductor materials. The semiconductor chip 410 is fixed to a lead frame 420 with a die-attach material 430, such as solder. The semiconductor chip 410 corresponds to the semiconductor device according to any one of the first to fifth embodiments.

A gate electrode 411 is connected to a gate lead 421 with a bonding wire 431. A source electrode 412 is connected to a source lead 422 with a bonding wire 432. A drain electrode 413 is connected to a drain lead 423 with a bonding wire 433. The bonding wires 431, 432, and 433 are made of a metal, such as Al. In the sixth embodiment, the gate electrode 411 is a gate electrode pad and is connected to the gate electrode 31 of the semiconductor device according to any one of the first to fifth embodiments. The source electrode 412 is a source electrode pad and is connected to the source electrode 32 of the semiconductor device according to any one of the first to fifth embodiments. The drain electrode 413 is a drain electrode pad and is connected to the drain electrode 33 or 133 of the semiconductor device according to any one of the first to fifth embodiments.

Subsequently, resin sealing is performed with a mold resin 440 by transfer molding. Hereby, a discretely packaged semiconductor device, such as a HEMT including GaN semiconductor materials, is produced.

The power supply device and high-frequency amplifier according to the sixth embodiment are described below. The power supply device and high-frequency amplifier according to the sixth embodiment include the semiconductor device according to any one of the first to fifth embodiments.

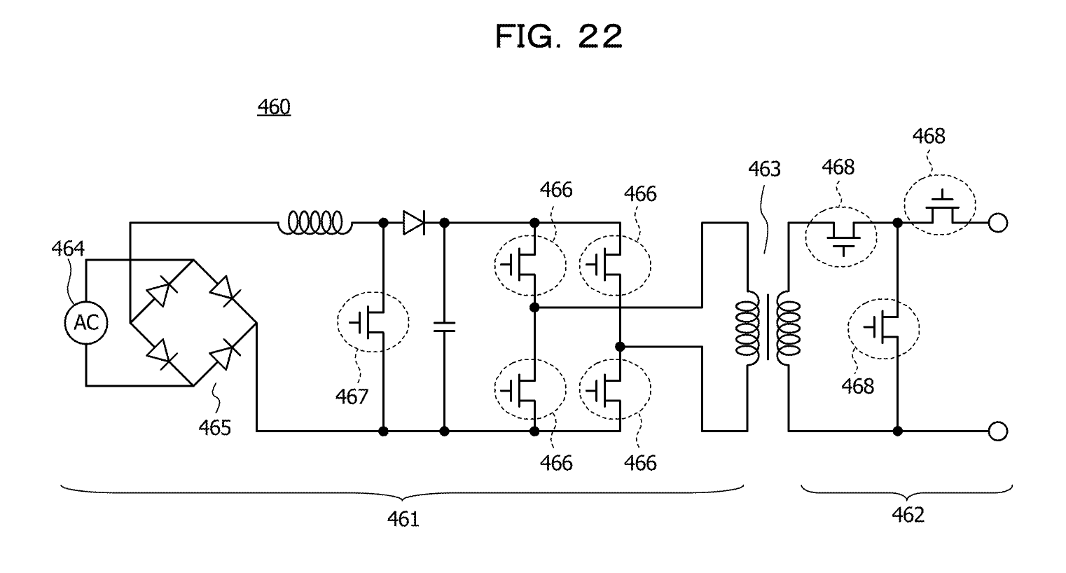

First, the power supply device according to the sixth embodiment is described below with reference to FIG. 22. A power supply device 460 according to the sixth embodiment includes a high-voltage primary circuit 461, a low-voltage secondary circuit 462, and a transformer 463 interposed between the primary circuit 461 and the secondary circuit 462. The primary circuit 461 includes an AC power source 464, a “bridge rectifier” 465, a plurality of switching elements 466 (four in the power supply device illustrated in FIG. 22), and one switching element 467. The secondary circuit 462 includes a plurality of switching elements 468 (three in the power supply device illustrated in FIG. 22). The power supply device illustrated in FIG. 22 includes the semiconductor devices according to any one of the first to fifth embodiments, which serve as switching elements 466 and 467 of the primary circuit 461. The switching elements 466 and 467 of the primary circuit 461 are preferably normally-off semiconductor devices. The switching elements 468 included in the secondary circuit 462 are common metal insulator semiconductor field effect transistors (MISFETs) composed of silicon.

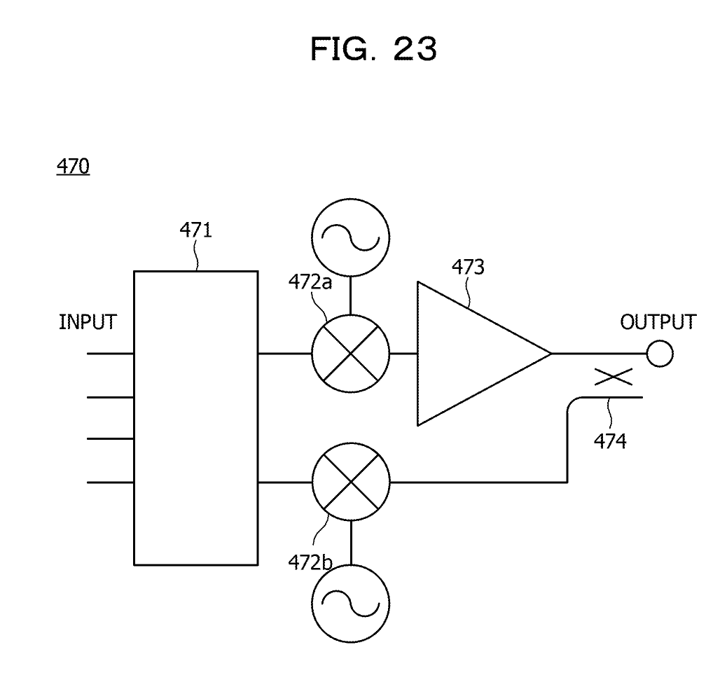

The high-frequency amplifier according to the sixth embodiment is described with reference to FIG. 23. A high-frequency amplifier 470 according to the sixth embodiment may be applied to, for example, a power amplifier used in a mobile phone base station. The high-frequency amplifier 470 includes a digital predistortion circuit 471, mixers 472, a power amplifier 473, and a directional coupler 474. The digital predistortion circuit 471 compensates for nonlinear distortion of an input signal. The mixers 472 mix the input signal the nonlinear distortion of which has been compensated for with an AC signal. The power amplifier 473 amplifies the input signal mixed with the AC signal. In the high-frequency amplifier illustrated in FIG. 23, the power amplifier 473 includes the semiconductor device according to any one of the first to fifth embodiments. The directional coupler 474 is used for, for example, monitoring the input and output signals. The circuit illustrated in FIG. 23 enables the output signal to be mixed with an AC signal in the mixer 472 and then transmitted to the digital predistortion circuit 471 by switching or the like.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a substrate;
a first semiconductor layer formed over the substrate, the first semiconductor layer being composed of a nitride semiconductor;
a second semiconductor layer formed over the first semiconductor layer, the second semiconductor layer being composed of a nitride semiconductor; and
a gate electrode, a source electrode, and a drain electrode that are formed over the second semiconductor layer, wherein
the source electrode including a plurality of protrusions that penetrate into the second semiconductor layer, and
the protrusions having a side surface inclined with respect to a surface of the first semiconductor layer.

2. The semiconductor device according to claim 1,
wherein the drain electrode includes a plurality of protrusions that penetrate into the second semiconductor layer, and
wherein the protrusions of the drain electrode have a side surface inclined with respect to the surface of the first semiconductor layer.

3. The semiconductor device according to claim 1, further comprising:
a third semiconductor layer interposed between the first semiconductor layer and the second semiconductor layer, the third semiconductor layer being composed of a nitride semiconductor.

4. The semiconductor device according to claim 3,
wherein edges of the protrusions are formed in the third semiconductor layer.

5. The semiconductor device according to claim 4,
wherein the third semiconductor layer is composed of a material containing AlN.

6. The semiconductor device according to claim 1,
wherein the angle θ at which the side surfaces of the protrusions are inclined with respect to the surface of the first semiconductor layer is 5° or more and 50° or less.

7. The semiconductor device according to claim 1,
wherein the angle θ at which the side surfaces of the protrusions are inclined with respect to the surface of the first semiconductor layer is 5° or more and 30° or less.

8. The semiconductor device according to claim 1,
wherein the width d of the protrusions on a side on which a surface of the second semiconductor layer is located is 20 nm or more and 400 nm or less.

9. The semiconductor device according to claim 1,
wherein the width d of the protrusions on a side on which a surface of the second semiconductor layer is located is 20 nm or more and 200 nm or less.

10. The semiconductor device according to claim 1,
wherein the area ratio of the protrusions in a cross section of the source electrode or the drain electrode, the cross section being taken along a surface of the second semiconductor layer, is more than 0% and 73% or less.

11. The semiconductor device according to claim 1,
wherein the area ratio of the protrusions in a cross section of the source electrode or the drain electrode, the cross section being taken along a surface of the second semiconductor layer, is 3% or more and 55% or less.

12. The semiconductor device according to claim 1,
wherein the first semiconductor layer is composed of a material containing GaN, and
wherein the second semiconductor layer is composed of a material containing InAlN or a material containing InAlGaN.

13. The semiconductor device according to claim 1,
wherein the first semiconductor layer is composed of a material containing GaN, and
wherein the second semiconductor layer is composed of a material containing AlN or a material containing AlGaN having an Al content of 0.5 or more.

14. The semiconductor device according to claim 1, further comprising:
a fourth semiconductor layer formed over the second semiconductor layer, the fourth semiconductor layer being composed of a nitride semiconductor.

15. The semiconductor device according to claim 1, further comprising:
an n-type semiconductor layer interposed between the second semiconductor layer and the protrusions, the n-type semiconductor layer being composed of an n-type nitride semiconductor.

16. A method for manufacturing a semiconductor device, the method comprising:
forming a first semiconductor layer over a substrate, the first semiconductor layer being composed of a nitride semiconductor;
forming a second semiconductor layer over the first semiconductor layer, the second semiconductor layer being composed of a nitride semiconductor;
forming a plurality of openings by wet etching in a portion of the second semiconductor layer in which a source electrode is to be formed;
filling the openings with a metal to form protrusions, and forming a source electrode including the protrusions over the second semiconductor layer;
forming a drain electrode over the second semiconductor layer; and
forming a gate electrode over the second semiconductor layer,
the protrusions having a side surface inclined with respect to a surface of the first semiconductor layer.

17. The method for manufacturing a semiconductor device according to claim 16, the method further comprising:
forming a plurality of openings in a portion of the second semiconductor layer in which the drain electrode is to be formed; and
filling the openings formed in the portion of the second semiconductor layer, in which the drain electrode is to be formed, with a metal to form a plurality of protrusions, and forming the drain electrode including the protrusions on the second semiconductor layer.

18. The method for manufacturing a semiconductor device according to claim 16,
wherein the first semiconductor layer is composed of a material containing GaN, and
wherein the second semiconductor layer is composed of a material containing InAlN or a material containing InAlGaN.

19. The method for manufacturing a semiconductor device according to claim 16,
wherein the first semiconductor layer is composed of a material containing GaN, and
wherein the second semiconductor layer is composed of a material containing AlN or a material containing AlGaN having an Al content of 0.5 or more.
